(19) United States
(12) Patent Application Publication
(10) Pub. No.: US 2007/0290758 A1
(43) Pub. Date: Dec. 20, 2007

(54) Electronic volume apparatus

(76) Inventors: Mitsuteru Sakai, Ukyo-Ku (JP); Yosuke Sato, Ukyo-Ku (JP)

Correspondence Address: CANTOR COLBURN, LLP, 55 GRIFFIN ROAD SOUTH, BLOOMFIELD, CT, 06002, US

(21) Appl. No.: 11/809,312

(22) Filed: May 31, 2007

(30) Foreign Application Priority Data
Jun. 2, 2006 (JP) JP2006-154321

(51) Int. Cl. H03G 3/10

(52) U.S. Cl. 330/281

(57) ABSTRACT

In an electronic volume apparatus, a gain having an initial value g1 at time t=0 in an initial state is transited to a target value g2 at time t=Tp after a certain transition period Tp elapses. A gain control unit controls the gain of the amplifier depending on a control function g(t) which satisfies the following conditions (1) to (3):

g(0)=g1, g(Tp)=g2; (1)

g′(Tp/2)>g′(0); and (2)

g′(Tp/2)>g′(Tp). (3)

where g′(t) is time differentiation of g(t).

### BACKGROUND OF THE INVENTION

1. Field of the Invention

The present invention relates to an electronic volume apparatus which controls a volume of an audio signal.

2. Description of the Related Art

An electronic device such as a CD player, an audio amplifier, a car stereo system, or a portable radio and portable audio player having a function of reproducing an audio signal generally includes a volume controller which adjusts a volume, an equalizer which adjusts frequency characteristics, and the like. The volume controller and the equalizer are controlled by changing an amplitude of an audio signal.

An audio signal is amplified by an amplifier and finally output as sound from a loudspeaker or headphones which is a sound output means. Volume adjustment is realized by controlling a gain of an amplifier or controlling a rate of decrease of an attenuator. For example, Japanese Patent Application Laid-open Nos. 2005-117489 and 2005-217710 disclose an electronic volume circuit which controls the gain of the amplifier and the rate of decrease of the attenuator by switching resistances of a variable resistor. Furthermore, Japanese Patent Application Laid-open No. 2004-222077 discloses a control technique for the electronic volume circuit.

[Patent Document 1] Japanese Patent Application Laid-open No. 2005-117489

[Patent Document 2] Japanese Patent Application Laid-open No. 2005-217710

[Patent Document 3] Japanese Patent Application Laid-open No. 2004-222077

When a volume is changed from an initial value to a target value, the resistance of a variable resistor of an electronic volume circuit must be switched from a value corresponding to the initial value to a value corresponding to the target value. At this time, when the resistances are sharply switched, a voltage value of an audio signal output from the amplifier sharply change to generate a signal component in an audio band. For this reason, the signal component causes noise to be generated.

### SUMMARY OF THE INVENTION

The present invention has been made in consideration of the above problems, and a general purpose of the present invention is to provide an electronic volume apparatus which can switch volumes while suppressing noise from being generated.

An embodiment of the present invention relates to an electronic volume apparatus which controls an amplitude of an audio signal. The electronic volume apparatus includes an amplifier which amplifies an input audio signal to change the amplitude and which can switch a plurality of gains, and a gain control unit which controls a gain of the amplifier. When a gain having an initial value g1 at time t=0 in an initial state is transited to a target value g2 at time t=Tp after a certain transition period Tp elapses, the gain control unit controls the gain of the amplifier depending on a control function g(t) which satisfies the following conditions (1) to (3):

g(0)=g1, g(Tp)=g2 (1)

g′(Tp/2)>g′(0) (2)

g′(Tp/2)>g′(Tp) (3)

where g′(t) is time differentiation of g(t). The control function g(t) is in differentiable at time t, g′(t) has an inclination of a minimum zone to t to t+Δt.

When the control function g(t) of the gain which influences generation of noise caused by switching volumes is set as described above, inclinations at the start and end of the transition of the gain are set to be smaller than an inclination at a point set between the start and the end. As a result, the noise can be considerably reduced. In this specification, the “gain of amplifier” may include a value smaller than 1. Therefore, the amplifier conceptually includes an attenuator.

The control function g(t) may be a function regulated depending on a target function f(t) defined as a trigonometric function which passes through points (0,g1) and (Tp,g2) and has a cycle of 2Tp.

When the control function is defined as the trigonometric function having the cycle of 2Tp, as a spectrum obtained by Fourier transformation, a main spectrum appears at a frequency of f=1/(2Tp), and a signal component in a frequency band higher than the frequency can be reduced. As a result, when the transition period Tp is appropriately set, a spectrum caused by transition of a volume can be concentrated on a band lower than the audio band, and noise can be reduced.

The control function g(t) may be a function which is regulated depending on a target function f(t) given by f(t)=A×cos(π×t/Tp)+B. In this case, A=(g1−g2)/2 and B=(g1+g2)/2 are satisfied.

The control function g(t) may be a function obtained by linearly interpolating division points obtained by dividing the target function f(t) by N (N is an integer which is not less than three) in a range of time t=0 to t=Tp.

When the target function is divided by N, quantized, and linearly interpolated, affinity to digital signal processing is improved to make it possible to make the configuration of the gain control unit simple.

The control function g(t) may be a function obtained by linearly interpolating division points obtained by equally dividing the target function f(t) by N in a direction of a dependent variable axis. The control function g(t) may be a function obtained by linearly interpolating division points obtained by equally dividing the target function f(t) by N in a direction of an independent variable. Sampling is equally divided by N to make it possible to make signal processing simpler.

Another embodiment of the present invention relates to an electronic volume apparatus. The electronic volume apparatus includes an amplifier which amplifies an input audio signal to change the amplitude and which can switch a plurality of gains, and a gain control unit which controls a gain of the amplifier. When a gain having an initial value g1 at time to in an initial state is transited to a target value g2 after a certain transition period Tp elapses, the gain control unit linearly changes the gain of the amplifier in M steps (M is an integer which is three or more). Furthermore, the gain of the amplifier is changed depending on a control function g(t) which satisfies the following conditions (4) to (7):

t_{M}=t₀+Tₚ (4)

g(t₀)=g1, g(t_{M})=g2 (5)

g′(tᵢ)>g′(t₀) (6)

g′(tᵢ)>g′(t_{M-1}) (7)

where i is an integer which satisfies 1≦i≦M−2, tᵢ is time at an ith division point, and g′(tᵢ) is an inclination at times tᵢ to tᵢ₊₁.

In this case, inclinations at the start and end of the transition of the gain are set to be smaller than an inclination at a halfway point set between the start and the end of the transition. As a result, noise can be considerably reduced.

The control function g(t) may be a function regulated depending on a target function f(t) defined as a trigonometric function which passes through points (0,g1) and (Tp,g2) and has a cycle of 2Tp.

The control function g(t) may be a function obtained by dividing a target function f(t) given by f(t)=A×cos(π×t/Tp)+B by M and linearly interpolating the division points. In this case, A=(g1−g2)/2 and B=(g1+g2)/2 are satisfied.

The control function g(t) may be regulated such that a Fourier transformation spectrum has a main component in a band of a speaker reproducible frequency or less or an audio band or less, for example, 20 Hz or less. In this case, when the above band is set as the main component, the spectrum is out of the audio band. For this reason, noise can be reduced.

The gain control unit may set a length of a transition period depending on a combination of an initial value and a target value. The gain control unit may set the transition period Tp such that the transition period Tp becomes short as a difference between the initial value and the target value decreases. In this case, a balance between time required for volume control and an amount of generated noise can be appropriately set.

The amplifier includes a resistor network constituted by a plurality of resistors and a plurality of switches arranged at connection points of the plurality of resistors. The amplifier may have a gain which is made variable by changing resistances of the resistor network depending on ON/OFF states of the plurality of switches. The gain control unit may include a digital control unit which outputs a digital value depending on the control function g(t) and a decoder circuit which ON/OFF-controls the plurality of switches of the amplifier depending on digital values output from the digital control unit.

The electronic volume apparatus may be integrated on a single semiconductor substrate. The “integrated” includes a case in which all constituent elements of the circuit are formed on a semiconductor substrate and a case in which main constituent elements of a circuit are integrally integrated. Some resistors and some capacitors may be formed outside the semiconductor substrate for adjusting a circuit constant.

According to still another embodiment of the present invention is an electronic device. The electronic device includes a reproducing unit which reproduces (playback) an audio signal, a volume control unit to which a volume value is input by a user, the electronic volume apparatus which amplifies an audio signal output from the reproducing unit depending on the volume value input to the volume control unit, and a sound output unit which outputs an output signal from the electronic volume apparatus.

According to the embodiment, in change in volume, since noise output from the sound output unit is reduced, a user can comfortably listen to sound.

Embodiments in which arbitrary combinations of the constituent elements and the constituent elements and the expressions of the present invention are replaced among a method, an apparatus, and a system is effective as embodiments of the present invention.

It is to be noted that any arbitrary combination or rearrangement of the above-described structural components and so forth is effective as and an encompassed by the present embodiments.

Moreover, this summary of the invention does not necessarily described all necessary features so that the invention may also be a sub-combination of these described features.

### BRIEF DESCRIPTION OF THE DRAWINGS

Embodiments will now be described, by way of example only, with reference to the accompanying drawings which are meant to be exemplary, not limiting, and wherein like elements are numbered alike in several Figures, in which:

FIG. 1 is a block diagram showing an entire configuration of an electronic apparatus using an electronic volume apparatus according to an embodiment;

FIG. 2 is a block diagram showing a configuration of a main part of the electronic volume apparatus according to the embodiment;

FIGS. 3A to 3C are circuit diagrams showing configurations of an amplifier in FIG. 2;

FIG. 4 is a block diagram showing a configuration example of the electronic volume apparatus according to the embodiment;

FIG. 5 is a waveform chart showing a target function f(t);

FIG. 6 is a waveform chart showing a control function g(t) obtained by quantizing the target function f(t);

FIG. 7 is a waveform chart showing another control function g(t) obtained by quantizing the target function f(t) in FIG. 5.

FIG. 8 is a wave form chart of an output signal from an amplifier in a change in volume; and

FIG. 9 is a Fourier spectrum of a control function g(t) shown in FIG. 6 or 7.

### DETAILED DESCRIPTION OF THE INVENTION

The invention will now be described based on preferred embodiments which do not intend to limit the scope of the present invention but exemplify the invention. All of the features and the combinations thereof described in the embodiment are not necessarily essential to the invention.

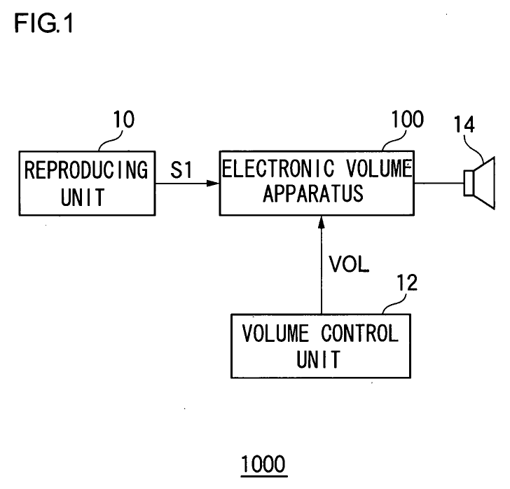

FIG. 1 is a block diagram showing an entire configuration of an electronic apparatus 1000 using an electronic volume apparatus 100 according to an embodiment. The electronic apparatus 1000 is an apparatus including a means which outputs sound, such as an audio amplifier, a car stereo system, a portable audio player, or a portable telephone. The electronic volume apparatus 100 according to the embodiment is mounted on the electronic apparatus 1000 to adjust a volume of sound output from a sound output unit such as a loudspeaker or an earphone.

The electronic apparatus 1000 includes the electronic volume apparatus 100, a reproducing unit 10, a volume control unit 12, and a sound output unit 14. The reproducing unit 10 is a block which converts sound data which is stored in a disk media, memory or a hard disk or wiredly or wirelessly input from the outside into an analog audio signal S1 to reproduce the audio signal. The volume control unit 12 is an input apparatus arranged to change a volume by a user, and a volume value VOL is designated through the volume control unit 12.

The electronic volume apparatus 100 amplifies the audio signal S1 output from the reproducing unit 10 depending on the volume value VOL input to the volume control unit 12. The electronic volume apparatus 100, as will be described below, includes an amplifier which amplifies or attenuates the audio signal S1. The electronic volume apparatus 100 changes a gain of an internal amplifier depending on the volume value designated by a user.

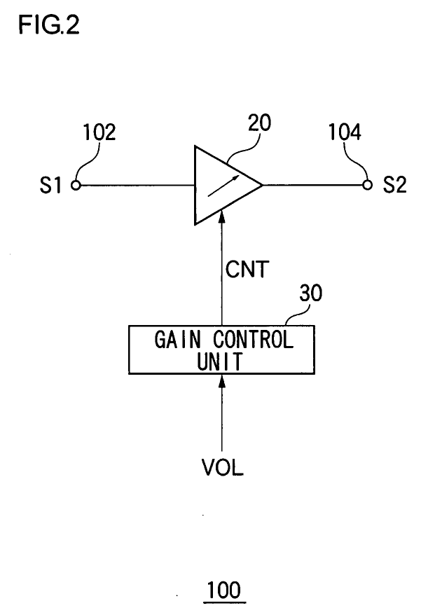

A configuration of the electronic volume apparatus 100 will be described below in detail. FIG. 2 is a block diagram showing a configuration of a main part of the electronic volume apparatus 100 according to the embodiment. The electronic volume apparatus 100 amplifies the audio signal S1 input to an input terminal 102 depending on the volume value VOL externally designated. An amplified audio signal S2 is output from an output terminal 104.

The electronic volume apparatus 100 includes an amplifier 20 and a gain control unit 30. The amplifier 20 is amplifier which amplifies an input audio signal S1 to change the amplitude. The amplitude is a concept which includes not only a gain more than 1 but also an attenuation equal to or less than 1. Therefore, the amplitude is a concept including an attenuator and means a circuit to widely change an amplitude of an electronic signal. As a gain of the amplifier 20, a plurality of gains discretely set is switchably set.

The gain control unit 30 outputs a gain control signal CNT to the amplifier 20. The gain control signal CNT corresponds to a control function g(t) (will be described later). The gain of the amplifier 20 moderately changes from an initial value g1 to a target value g2 according to a control function g(t) (will be described later).

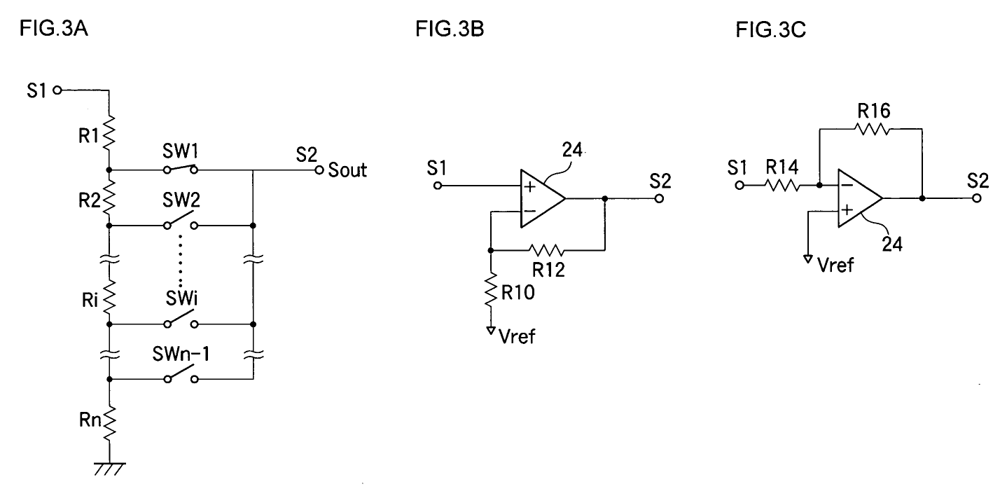

For example, the amplifier 20 is constituted by using a variable resistor. FIGS. 3A to 3C are circuit diagrams showing configurations of the amplifier 20. In FIG. 3A, a plurality of resistors R1 to Rn are connected in series with each other to form a resistor network. A potential at one end of the resistor network is fixed, and an audio signal S1 is applied to the other end. A plurality of switches SW1 to SWn−1 are arranged at connection nodes of the plurality of resistors R1 to Rn, respectively. A switch to be turned on is switched to make it possible to selectively output a voltage appearing at one of the plurality of connection nodes, and an attenuation rate is controlled.

In another example, as shown in FIG. 3B, an amplifier may be constituted as a non-inverting amplifier using an operational amplifier. The audio signal S1 is input to the non-inverting input terminal of an operational amplifier 24. A reference voltage Vref is applied to an inversion input terminal of the operational amplifier 24 through a resistor R10. A feedback resistor R12 is arranged between an output terminal and the inversion input terminal of the operational amplifier 24. In this case, at least one of the resistor R10 and the feedback resistor R12 is constituted by a variable resistor to make it possible to control again. The resistor constituted as the variable resistor, as shown in FIG. 3A, may be constituted by a resistor network including a plurality of resistors connected in series with each other and the plurality of switches.

In still another example, as shown in FIG. 3C, the amplifier can be constituted by an inversion amplifier using an operational amplifier. In this case, an audio signal S1 is input to the inversion input terminal of the operational amplifier 24 through an input resistor R14, and a reference voltage Vref is applied to the non-inverting input terminal. A feedback resistor R16 is arranged between the output terminal and the inversion input terminal of the operational amplifier. In this case, at least one of the input resistor R14 and the feedback resistor R16 is constituted by a variable resistor to make it possible to control a gain. The resistor constituted by the variable resistor, as shown in FIG. 3A, may be constituted by a plurality of resistor connected in series with each other, that is, a resistor network and a plurality of switches.

In this manner, in the embodiment, the configuration of the amplifier 20 is not limited to a specific type. The configuration of the amplifier 20 may be constituted such that a plurality of discretely set gains are switchably arranged.

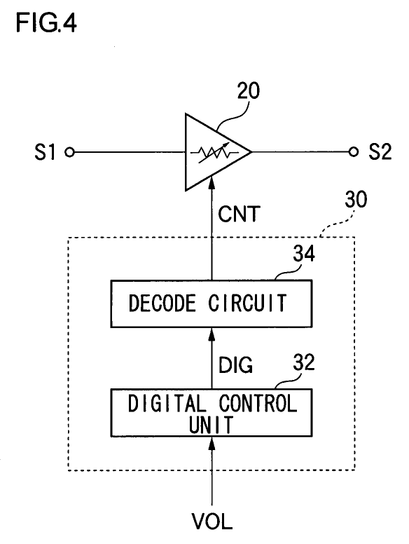

FIG. 4 is a block diagram showing a configuration example of the electronic volume apparatus 100. When the amplifier 20 is constituted by any one of the types in FIGS. 3A to 3C, the amplifier 20 includes at least a resistor network and a plurality of switches. Resistances of the resistor network are changed depending on ON/OFF states of the plurality of switches to make the gain variable.

The digital control unit 32 outputs a digital value DIG depending on the input volume value VOL. A decode circuit 34 ON/OFF-controls a plurality of switches in the amplifier 20 depending on the digital value DIG to set a gain corresponding to the volume value. More specifically, the gain control signal CNT is a signal to ON/OFF-control the plurality of switches in the amplifier 20.

When a user changes a gain having an initial value VOL1 in a certain state into a volume value VOL2, the gain control unit 30 changes the gain of the amplifier 20 from an initial value g1 corresponding to the volume value VOL1 to a target value g2 corresponding to the volume value VOL2. A method of controlling a gain by using the gain control unit 30 will be described below.

In the embodiment, the gain control unit 30 transits a gain of the amplifier 20 depending on the control function g(t) by using time as a parameter. The gain control unit 30 sets a transition period Tp depending on a combination of the initial value g1 and the target value g2 and transits a gain having the initial value g1 at time t=0 to the target value g2 at time t=Tp after the transition period Tp elapses.

The gain control unit 30 controls a gain of the amplifier 20 depending on a control function g(t) which satisfies the following conditions (1) to (3):

g(0)=g1, g(Tp)=g2 (1)

g′(Tp/2)>g′(0) (2)

g′(Tp/2)>g′(Tp) (3)

where g′(t) is time differentiation.

At the start and end of transition, when a variation in inclination of a gain, that is, a variation in amplitude (envelope) of an audio signal S1 is large, the audio signal S1 is easily sensed as noise. Therefore, when the control function g(t) which satisfies the condition (1) to (3) is set, inclinations of a gain at the start and end of transition are smaller than an inclination of a gain at a halfway point set between the start and the end of transition. As a result, noise can be preferably reduced.

For example, the control function g(t) maybe regulated depending on a target function f(t) defined as a trigonometric function which passes through points (0,g1) and (Tp,g2) and has a cycle of 2Tp. For example, the control function g(t) may be regulated depending on the target function f(t) defined by the following equations. The transition period Tp is preferably set within the range of 10 ms to 100 ms.

f(t)=A×cos(π×t/Tp)+B

A=(g1−g2)/2

B=(g1+g2)/2

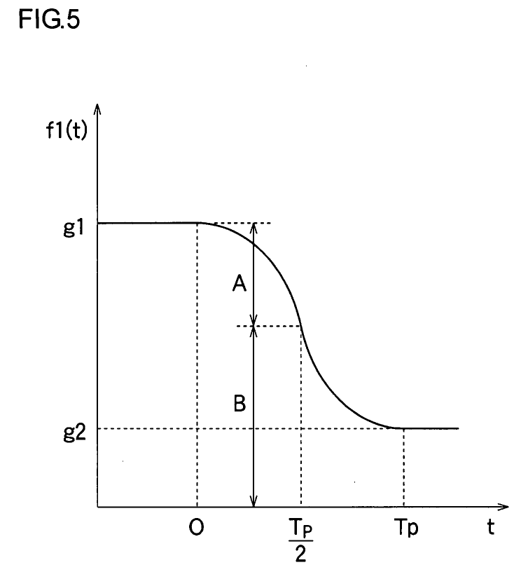

FIG. 5 is a wave form chart of the target function f(t) FIG. 5 shows a waveform obtained when g1>g2 is satisfied, that is, when a volume is reduced. However, even though g1<g2 is satisfied, a gain changes according to the trigonometric function. In the following waveform chart or the like, an ordinate and an abscissa are properly extended and reduced to make it easy to understand the waveform chart, and each waveform is properly simplified to make it easy to understand the waveform.

As the control function g(t), the target function f(t) itself may be used. The control function g(t) may be a function obtained by quantizing the target function f(t). A method of setting the control function g(t) will be described below.

### FIRST SETTING EXAMPLE

In a first setting example, as the control function g(t), the target function f(t) itself is defined. In this case, in the digital control unit 32 in FIG. 4, a trigonometric function may be calculated as a function of time t, and a digital value DIG may be output. A storing means such as a resistor may be arranged in the digital control unit 32 to record the time t and the value of the trigonometric function in association with each other, and the values may be read in each case.

### SECOND SETTING EXAMPLE

In a second setting example, as the control function g(t), a function by quantizing the target function f(t) is defined. The target function f(t) is divided by N (N is an integer which is not less than three) in a range of time t=0 to t=Tp. A division point obtained by the division is linearly interpolated.

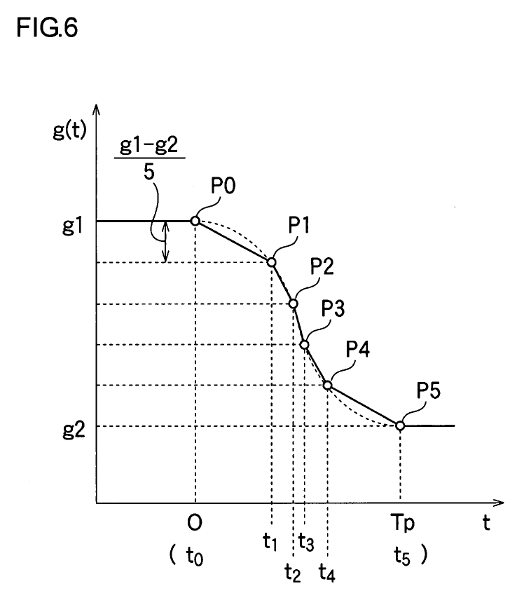

FIG. 6 is a waveform chart showing the control function g(t) obtained by quantizing the target function f(t) in FIG. 5. The control function g(t) in FIG. 6 is obtained when N=5 is satisfied. A range of g1 to g2 along a vertical axis of the target function f(t) is equally divided by N=5 in a direction of a dependent variable. The control function g(t) is a function obtained by linearly interpolating division points p0 to p5 obtained as described above.

### THIRD SETTING

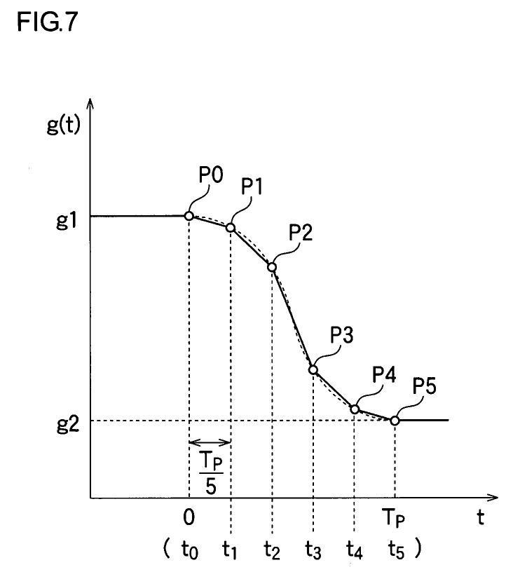

FIG. 7 is a waveform chart showing another control function g(t) obtained by quantizing the target function f(t) in FIG. 5. The control function g(t) in FIG. 7 is obtained by equally dividing the target function f(t) by N in a direction of an independent variable axis (time axis).

Even though the control function g(t) is regulated by any one of the first to third setting examples, the above conditions (1) to (3) are satisfied. In the examples in FIGS. 6 and 7, the target function f(t) is equally divided in the direction of the dependent variable axis and the direction of the independent variable axis (time axis). However, the invention is not limited to the examples, and intervals between division points need not be equal to each other. In this case, division points may be set to minimize noise by an experiment to regulate the control function g(t).

An operation of the electronic volume apparatus 100 having the above configuration will be described below. A user changes a volume of the electronic volume apparatus 100 with reproducing audio data at a certain volume value of VOL1 by the volume control unit 12 when a certain initial value VOL1 is set. As a result, from the volume control unit 12, a changed volume value VOL2 is sent to the electronic volume apparatus 100.

The gain control unit 30 of the electronic volume apparatus 100 which receives the changed volume value VOL2 generates a control function g(t) regulated depending on the target function f(t) from the initial value g1 and the target value g2 of the gain of the amplifier 20 in the digital control unit 32. From transition start time t=0, a digital value DIG depending on the control function g(t) is output to the decode circuit 34. The decode circuit 34 turns on or off the switches in the amplifier 20 depending on the digital value DIG to change gains.

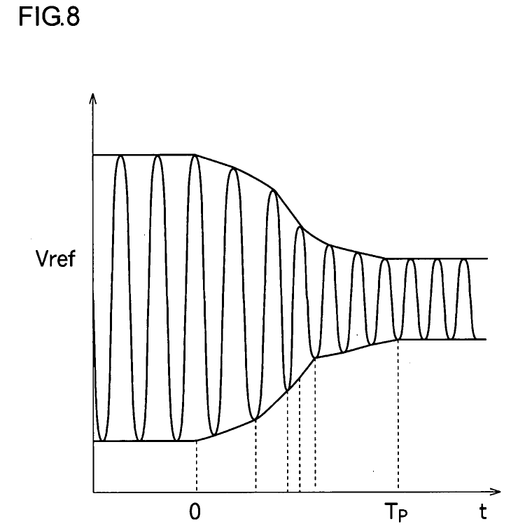

FIG. 8 is a waveform chart of an output signal S2 from the amplifier 20 in a change in volume. FIG. 8 shows, as an example, a case in which a gain is changed according to the control function g(t) in FIG. 6. At time t=0, an amplified audio signal S2 having an amplitude corresponding to the initial value g1 gradually decreases in amplitude with transition of the gain. At time t=Tp after the transition period Tp elapses, the amplitude changes into an amplitude corresponding to the target value g2.

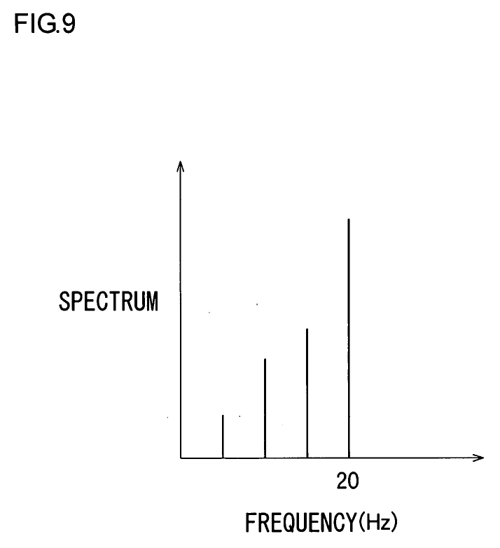

FIG. 9 is a Fourier spectrum of the control function g(t) shown in FIG. 6 or 7. A human audio band has a lower limit of 15 Hz to 20 Hz and an upper limit of about 20 kHz. For example, when transition time is given by Tp=25 ms, cycle time of a triangular wave is given by 2Tp=50 ms, and a frequency is 20 Hz. In this case, as shown in FIG. 9, a Fourier transformation spectrum of the control function g(t) has a main component in a not more than 20 Hz. Therefore, since noise caused by switching volumes is out of the audio band, audible noise can be reduced. When the transition period Tp is set to be long, the main component of the spectrum shifts to a lower frequency. For this reason, the audible noise is further reduced.

The gain control unit 30 may set the length of the transition period Tp depending on a combination of the initial value g1 and the target value g2 of the gain. For example, as the difference between the initial value g1 and the target value g2 decreases, the gain control unit 30 may set the transition period Tp to be short. Since a small difference between the initial value g1 and the target value g2 means a small volume difference, noise is not easily sensed by the human ear. Therefore, when the transition period Tp is regulated depending on the combination between the initial value g1 and the target value g2, the volume can be changed within a short period of time while suppressing audible noise.

As described above, in the electronic volume apparatus 100 according to the embodiment, audible noise generated by a change in volume value of an audio signal can be reduced. In particular, a triangular wave is defined as the target function f(t), so that noise can be preferably reduced.

When the control function g(t) is generated by dividing the target function f(t) by N and linearly interpolating the division points, affinity to a digital signal processing circuit using a counter or the like is improved. For this reason, the digital value DIG can be easily generated. Furthermore, it is advantageously unnecessary that a control function is held in a memory such as a table.

The settings of the control function g(t) and the target function f(t) by the gain control unit 30 described above and the gain control method can be recognized as follows.

More specifically, when a gain of the amplifier having the initial value g1 at time t₀ in the initial state is transited to the target value g2 after a certain transition period Tp elapses, the gain control unit 30 linearly changes the gain in M steps (M is an integer which is three or more). The gain control unit 30 changes the gain of the amplifier 20 depending on the control function g(t) which satisfies the following conditions (4) to (7):

t_{M}=t₀+Tp Condition (4)

g(t₀)=g1, g(t_{M})=g2 Condition (5 )

g′(tᵢ)>g′(t₀) Condition (6)

g′(tᵢ)>g′(t_{M-}1) Condition (7)

where i is an integer which satisfies 1≦i≦M−2, tᵢ is time at an ith division point, and g′(tᵢ) is an inclination of g(t) at time tᵢ to t_{i+1.}

A trigonometric function having a cycle of 2Tp is defined as a target function f(t). The control function g(t) is regulated depending on the target function f(t). For example, the target function f(t) is defined by the following equations:

f(t)=A×cos(π×t/Tp)+B

A=(g1−g2)/2

B=(g1+g2)/2

where t=0 corresponds to transition start time t₀.

Furthermore, the control function g(t) is regulated as a function obtained by dividing the target function f(t) by M and linearly interpolating division points.

The control function g(t) regulated by the design method recognized as described above is equivalent to control functions shown in FIGS. 5 to 7. Therefore, even though gain control is performed on the basis of the control function g(t), audible noise in a change in volume can be advantageously reduced.

The embodiment according to the present invention has been described. The above embodiment is an exemplification. It is understood by a person skilled in the art that combinations of the constituent elements and the processing processes can be variably modified and that the modifications are included in the spirit and scope of the invention.

In the embodiment, the target function f(t) is mainly set as a trigonometric function, and the control function g(t) is regulated depending on the target function. However, the present invention is not limited to the embodiment. For example, the target function f(t) maybe regulated as a part of a trigonometric function the cycle of which is set to be longer than 2Tp. The control function g(t) is not necessarily regulated after the target function f(t) is set. The control function g(t) can be directly regulated to satisfy the above conditions (1) to (3).

In the explanation of the embodiment, volume is changed. However, the application of the electronic volume apparatus 100 is not limited to the change in volume. The electronic volume apparatus 100 may be applied to an equalizer or the like which controls gains for every certain frequency. In the explanation of the embodiment, volume is changed. However, the present invention can also be applied to a mute process in stopping of reproduction.

While the preferred embodiments of the present invention have been described using specific terms, such description is for illustrative purposes only, and it is to be understood that changes and variations may be made without departing form the spirit or scope of the appended claims.

What is claimed is:

1. An electronic volume apparatus comprising:
an amplifier which amplifies an input audio signal to change the amplitude and which can switch a plurality of gains; and
a gain control unit which controls a gain of the amplifier,
wherein
when a gain having an initial value g1 at time t=0 in an initial state is transited to a target value g2 at time t=Tp after a certain transition period Tp elapses,
the gain control unit controls the gain of the amplifier depending on a control function g(t) which satisfies the following conditions (1) to (3):
g(0)=g1, g(Tp)=g2; (1)
g′(Tp/2)>g′(0); and (2)
g′(Tp/2)>g′(Tp). (3)
where g′(t) is time differentiation of g(t).

2. The electronic volume apparatus according to claim 1, wherein
the control function g(t) may be a function regulated depending on a target function f(t) defined as a trigonometric function which passes through points (0,g1) and (Tp,g2) and has a cycle of 2Tp.

3. The electronic volume apparatus according to claim 2, wherein
the control function g(t) is a function which is regulated depending on a target function f(t) given by:
f(t)=A×cos(π×t/Tp)+B,
A=(g1−g2)/2, and
B=(g1+g2)/2.

4. The electronic volume apparatus according to claim 2, wherein
the control function g(t) is a function obtained by linearly interpolating division points obtained by dividing the target function f(t) by N (N is an integer which is not less than three) in a range of time t=0 to t=Tp.

5. The electronic volume apparatus according to claim 3, wherein
the control function g(t) is a function obtained by linearly interpolating division points obtained by dividing the target function f(t) by N (N is an integer which is not less than three) in a range of time t=0 to t=Tp.

6. The electronic volume apparatus according to claim 4, wherein
the control function g(t) is a function obtained by linearly interpolating division points obtained by equally dividing the target function f(t) by N in a direction of a dependent variable axis.

7. The electronic volume apparatus according to claim 4, wherein
the control function g(t) may be a function obtained by linearly interpolating division points obtained by equally dividing the target function f(t) by N in a direction of an independent variable.

8. The electronic volume apparatus comprising:
an amplifier which amplifies an input audio signal to change the amplitude and which can switch a plurality of gains; and
a gain control unit which controls a gain of the amplifier,
wherein
when a gain having an initial value g1 at time to in an initial state is transited to a target value g2 after a certain transition period Tp elapses,
the gain control unit linearly changes the gain of the amplifier in M steps (M is an integer which is not less than three), and the gain of the amplifier is changed depending on a control function g(t) which satisfies the following conditions (4) to (7):
t_{M}=t₀+Tₚ (4)
g(t₀)=g1, g(t_{M})=g2 (5)
g′(tᵢ)>g′(t₀) (6)
g′(tᵢ)>g′(t_{M-1}) (7)
where i is an integer which satisfies 1≦i≦M−2, tᵢ is time at an ith division point, and g′(tᵢ) is an inclination at times tᵢ to tᵢ₊₁.

9. The electronic volume apparatus according to claim 8, wherein
the control function g(t) is a function regulated depending on a target function f(t) defined as a trigonometric function which passes through points (0,g1) and (Tp,g2) and has a cycle of 2Tp.

10. The electronic volume apparatus according to claim 9, wherein
the control function g(t) is a function obtained by dividing a target function f(t) given by:
f(t)=A×cos(π×t/Tp)+B;
A=(g1−g2)/2; and
B=(g1 +g2)/2
by M and linearly interpolating the division points.

11. The electronic volume apparatus according to claim 1, wherein
the control function g(t) is regulated such that a Fourier transformation spectrum has a main component in a band not more than 20 Hz.

12. The electronic volume apparatus according to claim 8, wherein
the control function g(t) is regulated such that a Fourier transformation spectrum has a main component in a band not more than 20 Hz.

13. The electronic volume apparatus according to claim 1, wherein
the gain control unit sets a length of a transition period depending on a combination of an initial value and a target value.

14. The electronic volume apparatus according to claim 8, wherein
the gain control unit sets a length of a transition period depending on a combination of an initial value and a target value.

15. The electronic volume apparatus according to claim 13, wherein
the gain control unit sets the transition period such that the transition period becomes short as a difference between the initial value and the target value decreases.

16. The electronic volume apparatus according to claim 1, wherein the amplifier includes:
a resistor network constituted by a plurality of resistors; and
a plurality of switches arranged at connection points of the plurality of resistors, and the amplifier has a gain which is made variable by changing resistances of the resistor network depending on ON/OFF states of the plurality of switches, wherein
the gain control unit includes:
a digital control unit which outputs a digital value depending on the control function g(t); and
a decoder circuit which ON/OFF-controls the plurality of switches of the amplifier depending on digital values output from the digital control unit.

17. The electronic volume apparatus according to claim 1, wherein
the electronic volume apparatus is integrated on a single semiconductor substrate.

18. An electronic apparatus comprising:
a reproducing unit which reproduces an audio signal;
a volume control unit to which a volume value is input by a user;
the electronic volume apparatus according to claim 1 which amplifies an audio signal output from the reproducing unit depending on the volume value input to the volume control unit; and
a sound output unit which outputs an output signal from the electronic volume apparatus.

19. A method for controlling a gain of an amplifier which amplifies an input audio signal to change the amplitude and which can switch a plurality of gains, wherein
when a gain having an initial value g1 at time t=0 in an initial state is transited to a target value g2 at time t=Tp after a certain transition period Tp elapses, the gain of the amplifier is controlled depending on a control function g(t) which satisfies the following conditions (1) to (3):
g(0)=g1, g(Tp)=g2; (1)
g′(Tp/2)>g′(0); and (2)
g′(Tp/2)>g′(Tp). (3)
where g′(t) is time differentiation of g(t).

20. A method for controlling a gain of an amplifier which amplifies an input audio signal to change the amplitude and which can switch a plurality of gains, wherein
when a gain of the amplifier having an initial value g1 at time t₀ in an initial state is transited to a target value g2 after a certain transition period Tp elapses, the gain of the amplifier is linearly changed in M steps (M is an integer which is not less than three), and the gain of the amplifier is changed depending on a control function g(t) which satisfies the following conditions (4) to (7):
t_{M}=t₀+Tₚ (4)
g(t₀)=g1, g(t_{M})=g2 (5)
g′(tᵢ)>g′(t₀) (6)
g′(tᵢ)>g′(t_{M-1}) (7)
where i is an integer which satisfies 1≦i≦M−2, tᵢ is time at an ith division point, and g′(tᵢ) is an inclination at times tᵢ to tᵢ₊₁.
